(19) United States
(12) Patent Application Publication
(10) Pub. No.: US 2012/0168837 A1
(43) Pub. Date: Jul. 5, 2012

(54) Ferroelectric Memory Electrical Contact

(75) Inventors: Steven Craig BARTLING, Plano, TX (US); Michael Patrick CLINTON, Allen, TX (US); Borna OBRADOVIC, McKinney, TX (US)

(73) Assignee: TEXAS INSTRUMENTS INCORPORATED, Dallas, TX (US)

(21) Appl. No.: 13/312,352

(22) Filed: Dec. 6, 2011

Related U.S. Application Data
(60) Provisional application No. 61/428,345, filed on Dec. 30, 2010.

(51) Int. Cl. H01L 27/115; H01L 21/8246

(52) U.S. Cl. 257/295; 438/3; 257/E21.663; 257/E27.104

(57) ABSTRACT

A ferroelectric apparatus includes a circuit having a first capacitor electrically coupled to a plate line via a top terminal connection of the first ferroelectric capacitor and to a storage node via a bottom terminal connection of the first ferroelectric capacitor. The circuit also includes a second ferroelectric capacitor electrically coupled to a second plate line via a second bottom terminal connection of the second ferroelectric capacitor and to the storage node via a second top terminal connection of the second ferroelectric capacitor.

### RELATED APPLICATIONS

This application claims the benefit of U.S. Provisional Application No. 61/428,345 filed Dec. 30, 2010, which is incorporated by reference in its entirety herein.

### TECHNICAL FIELD

This invention relates generally to memory devices and more specifically to ferroelectric electric memory devices.

### BACKGROUND

Various types of memory devices are known in the art for storing data used by various kinds of computing devices. Generally, memories include elements that can take one of two or more states wherein each state corresponds to a logical element used by an associated computing device. For example, many memory devices include elements that can be maintained in two states, one corresponding to a logic “zero” and a second corresponding to a logic “one.” One example of a known memory device is a ferroelectric memory, also known as ferroelectric random access memory (FRAM or FeRAM). In a ferroelectric memory device, the element that can assume two states is a ferroelectric capacitor.

A ferroelectric capacitor, when biased with a voltage, maintains a stable remnant polarization when the bias voltage is removed. The ferroelectric capacitor can maintain this remnant polarization without application of an outside power source. So configured, a ferroelectric device based memory can maintain its stored state in the absence of the application of electricity, thereby making it a low-power option for a memory device. When a ferroelectric memory device is read, a voltage is applied to the ferroelectric capacitor and the amount of current that flows from the ferroelectric capacitor indicates the ferroelectric capacitor's previous state. Two ferroelectric capacitors can be used together to boost the signal to noise ratio relative to using only one ferroelectric capacitor.

One typical arrangement for a two ferroelectric capacitor system is to arrange the ferroelectric capacitors in a voltage divider arrangement wherein during a read cycle a voltage is applied to the ferroelectric capacitors arranged in series and the output signal is read from the node between the two ferroelectric capacitors. For typical silicon builds in integrated circuits, the ferroelectric capacitor is sandwiched between a polycrystalline silicon layer (commonly known as “poly”) and a metal layer (commonly known as a “metal1” layer) or between two metal layers (commonly known as “metal1” and “metal2” layers). In either arrangement the ferroelectric capacitors are arranged to minimize the footprint in the silicon build (i.e., use the least amount of silicon area in a given circuit). This accepted method of arranging two ferroelectric capacitors in a voltage divider arrangement in a silicon build, however, results in the inability to discriminate between a logic 0 and logic 1 with too pairs of ferroelectric capacitors being unable to distinguish between a logic 0 and logic 1 during a read operation because the signal (usually voltage, but current is possible) obtained when reading a logic 1 is too close to the voltage obtained when reading a logic 0 to be resolvable within the signal to noise discrimination ability of a sense amplifier.

### SUMMARY

Generally speaking, pursuant to these various embodiments, a ferroelectric memory apparatus includes a circuit having a first capacitor electrically coupled to a plate line via a top terminal connection of the first ferroelectric capacitor and to a storage node via a bottom terminal connection of the first ferroelectric capacitor. The circuit also includes a second ferroelectric capacitor electrically coupled to a second plate line via a second bottom terminal connection of the second ferroelectric capacitor and to the storage node via a second top terminal connection of the second ferroelectric capacitor. So configured, the general rule of designing silicon based devices to have the smallest possible footprint is sacrificed to improve the magnitude of the voltage difference between the read of a logic 0 and the read of a logic 1 (the signal differential) for the ferroelectric memory apparatus. The improved voltage differential improves reliability of the ferroelectric memory apparatus over arrangements made in accord with the general rule. These and other benefits may become clearer upon making a thorough review and study of the following detailed description.

### BRIEF DESCRIPTION OF THE DRAWINGS

FIG. 1 comprises a circuit diagram of an example expected approach to designing a ferroelectric circuit having a voltage divider arrangement between two plate lines;

FIG. 2 comprises a side view of an example silicon build for the circuit of FIG. 1;

FIG. 3 comprises a circuit diagram of the circuit of FIG. 1 as configured during a WRITE operation for the circuit;

FIG. 4 comprises hysteresis curves for each of the ferroelectric capacitors of the circuit of FIG. 1, the curves showing the change of the polarization of the capacitor in response to application of an applied voltage;

FIG. 5 comprises a circuit diagram of the circuit of FIG. 1 as configured during a READ operation for the circuit;

FIG. 6. comprises a circuit diagram of an example approach to designing a ferroelectric circuit having a voltage divider arrangement between two plate lines as configured in accordance with various embodiments of the invention;

FIG. 7 comprises a side view of an example silicon build for the circuit of FIG. 6;

FIG. 8 comprises a plan view of example silicon builds for the circuit of FIG. 1;

FIG. 9 comprises a plan view of example silicon builds for the circuit of FIG. 6;

FIG. 10 comprises a circuit diagram of the circuit of FIG. 6 as configured during a WRITE operation for the circuit;

FIG. 11 comprises hysteresis curves for each of the ferroelectric capacitors of the circuit of FIG. 6, the curves showing the change of the polarization of the capacitor in response to application of an applied voltage;

FIG. 12 comprises a circuit diagram of the circuit of FIG. 6 as configured during a READ operation for the circuit;

FIG. 13 comprises a flow diagram of an example method of building a ferroelectric circuit as configured in accordance with various embodiments of the invention;

FIG. 14 comprises a flow diagram of an example method of operation of a ferroelectric circuit as configured in accordance with various embodiments of the invention.

Skilled artisans will appreciate that elements in the figures are illustrated for simplicity and clarity and have not necessarily been drawn to scale. For example, the dimensions and/or relative positioning of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments. It will further be appreciated that certain actions and/or steps may be described or depicted in a particular order of occurrence while those skilled in the art will understand that such specificity with respect to sequence is not actually required. It will also be understood that the terms and expressions used herein have the ordinary technical meaning as is accorded to such terms and expressions by persons skilled in the technical field as set forth above except where different specific meanings have otherwise been set forth herein.

### DETAILED DESCRIPTION

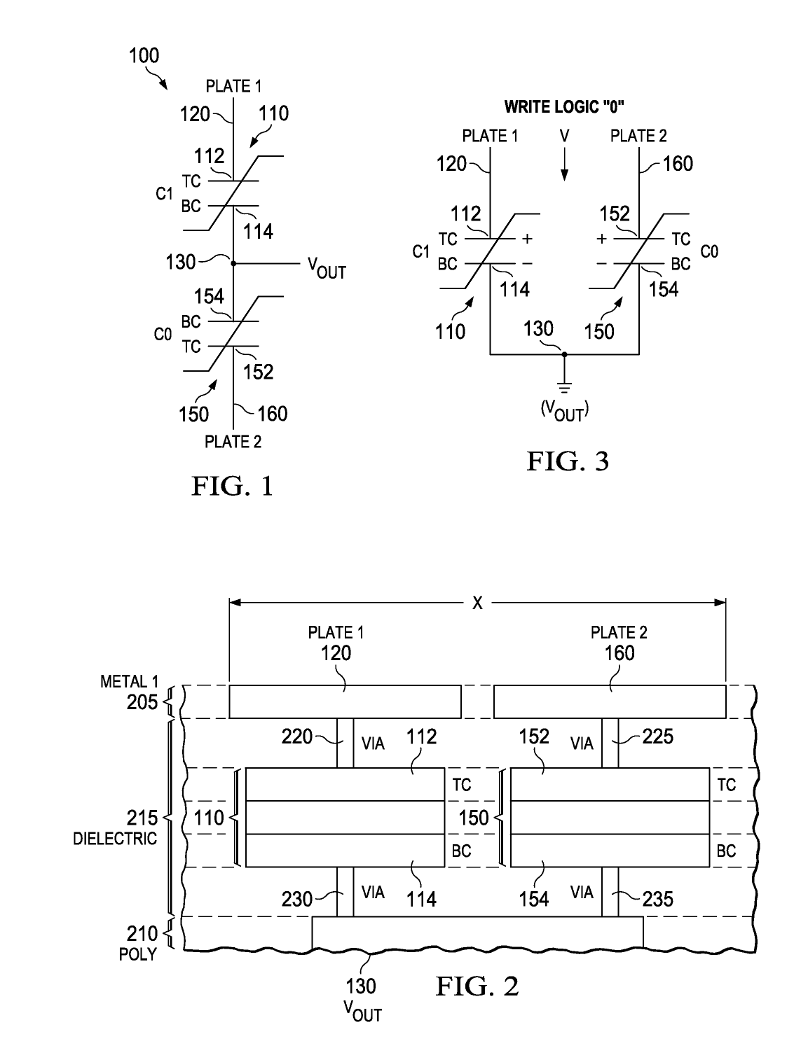

With reference to FIG. 1, an example ferroelectric memory apparatus 100 having a traditional voltage divider electrical layout includes a first ferroelectric capacitor C1 110 with a top connection 112 electrically connected to a first top plate 120 and a bottom connection 114 electrically connected to a storage node 130. A second ferroelectric capacitor C0 150 has a top connection 152 electrically coupled to a second plate line 160 and a bottom connection 154 electrically connected to the storage node 130.

This arrangement of top connections and bottom connections for the ferroelectric capacitors C1 and C0 is the typical arrangement reached by those of skill in the art when designing a voltage divider arrangement for two ferroelectric capacitors because this arrangement results is the smallest footprint in an integrated circuit. With reference to FIG. 2, one example layout in an integrated circuit will be described. For typical silicon builds, the ferroelectric capacitor is sandwiched between a polycrystalline silicon layer (commonly known as “poly”) and a metal layer (commonly known as a “metal1” layer) or between two metal layers (commonly known as “metal1” and “metal2” layers although the build can be made between any arbitrary metal layers). In FIG. 2, the ferroelectric capacitors are sandwiched between a metal1 layer 205 and a poly layer 210, although the teachings of this application are applicable to building the capacitors between any integrated circuit layers. In the typical arrangement shown in FIG. 2, the plate line 1 120 and plate line 2 160 are disposed in the metal1 layer 205. The ferroelectric capacitors 110 and 150 are built in the dielectric layer 215 between the metal1 layer 205 and poly layer 210. An electric connection is established between the top connection 112 and the plate 1 210 by a via 220. Similarly, an electric connection is established between the top connection 152 of the second ferroelectric capacitor 150 and the plate 2 160 by a via 225. The terms “top connection” and “bottom connection” refer to the relative arrangement of the ferroelectric capacitor builds within the integrated circuit build, and such terms are fully interchangeable and not intended to restrict understanding of the orientation of the ferroelectric capacitor to a particular physical alignment.

The storage node 130 is built in the poly layer 210 and is electrically connected to the bottom connection 114 of the first ferroelectric capacitor 110 by a via 230 and to the bottom connection 154 of the second ferroelectric capacitor 150 by a via 235. Because a simple vertical connection can be made between the various elements, the footprint, indicated by the length “X” from end to end of the circuit portion, can be quite compact. Because space in an integrated circuit is always conserved whenever possible, the physical arrangement of the two capacitor voltage divider type design shown in FIG. 2 is the preferred design.

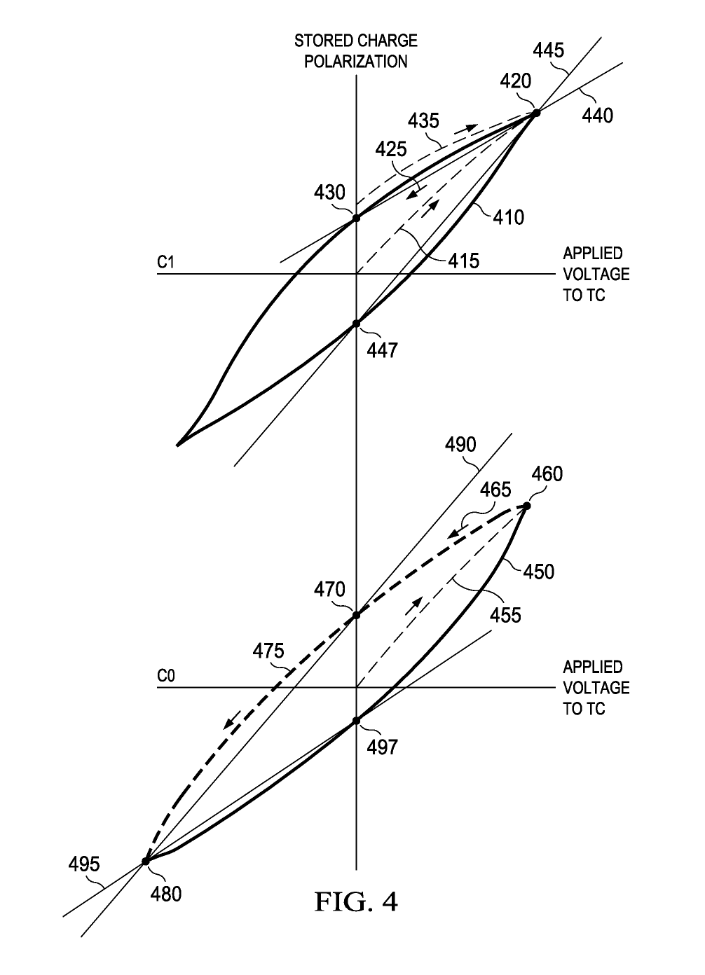

The operation of such a design will be described with reference to FIGS. 3-5. During a “WRITE” operation where data is stored in the circuit (in this example a logic “0”), the storage node 130 is driven to a potential equal to ground potential (representing a logic “0” on the storage node). Subsequently, a positive voltage V is applied to both plate line 1 120 and plate line 160 while the storage node 130 is held at ground potential. The voltage V polarizes the ferroelectric capacitors 110 and 150 such that each is left with a remnant polarization after the voltage V is removed. This process is demonstrated with reference to FIG. 4, which shows typical hysteresis curves 410 and 450 of ferroelectric capacitors 110 and 150, respectively. The hysteresis curves 410 and 450 are plotted to show the stored charge or polarization of the ferroelectric capacitor on the y-axis against an applied voltage along the x-axis. The curves 410 and 450 have an elongated shape that is typical of ferroelectric capacitors. When the voltage V is a positive voltage applied to the ferroelectric capacitors 110 and 150, because both have top connections 112 and 152 connected to the plate lines 1 and 2, the polarization tracks upward toward a first saturation point. For the first ferroelectric capacitor 110, the polarization tracks upward along dashed line 415 to the saturation point 420. For the second ferroelectric capacitor 150, the polarization tracks upward along dashed line 455 to the saturation point 460. When the voltage V is removed from the ferroelectric capacitors 110 and 150, the polarization moves along the hysteresis curves for each capacitor. For the first ferroelectric capacitor 110, the polarization travels along dashed line 425 on the hysteresis curve 410 to a steady state polarization point 430 with zero applied voltage. The polarization of the second ferroelectric capacitor 150 moves along dashed line 465 on the hysteresis curve 450 to a steady state polarization point 470 with zero applied voltage.

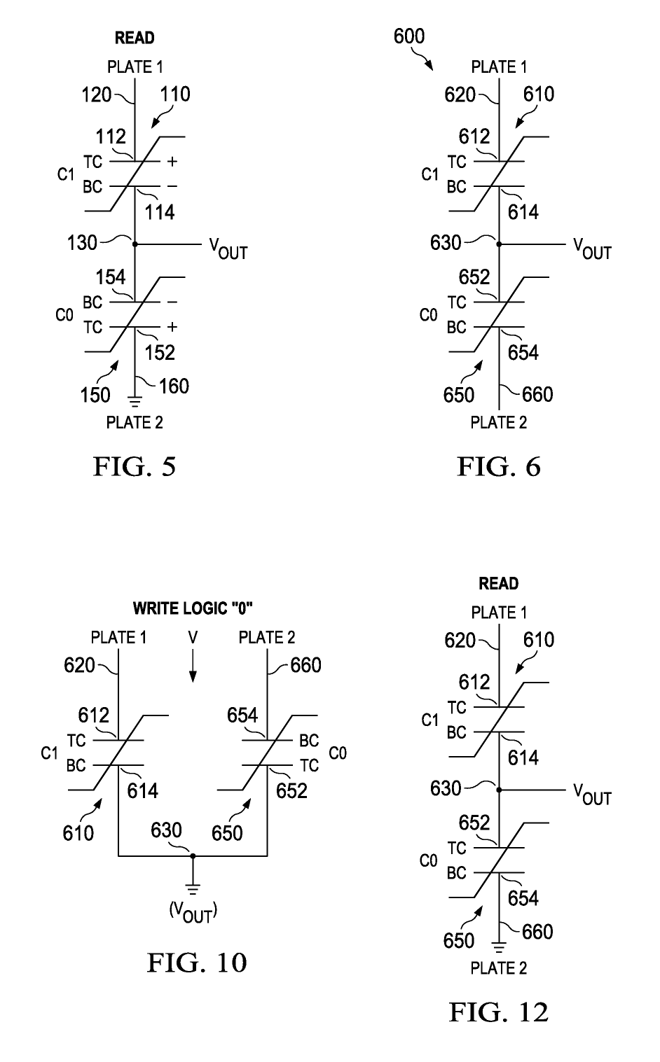

With reference to FIG. 5, during a “READ” operation where data stored in the circuit is read from the ferroelectric capacitors 110 and 150, plate line 1 120 is pulsed with a positive voltage while plate line 2 160 is maintained at ground potential (although the operation of the respective plate lines can be interchanged to provide effectively similar electrical response). The storage node 130 then reads the signal (such as voltage or current) produced by the ferroelectric capacitors 110 and 150 in response to the voltage pulse. One skilled in the art will recognize that the signal out at the storage node 130 in this voltage divider type of arrangement will be the pulsed voltage (or corresponding current) multiplied by a ratio of the capacitances of the two ferroelectric capacitors 110 and 150. For ferroelectric capacitors, the capacitance is determined by the slope of the line that the polarization travels on a ferroelectric capacitor's particular hysteresis curve.

Referring again to FIG. 4, when a positive pulse voltage is applied to plate line 1 120 during a READ operation, the positive voltage is applied to the top connection 112 of the first ferroelectric capacitor 110, which drives the polarization of the capacitor 110 back up the hysteresis curve 410 from the steady state point 430 along dashed line 435 back to the saturation point 420. Accordingly, the capacitance of the first ferroelectric capacitor 110 corresponds to the slope of the line 440.

The positive pulse voltage applied to plate line 1 120 during the READ operation applies a positive voltage to the bottom connection 154 of the second ferroelectric capacitor 150. From the point of view of the second ferroelectric capacitor 150, this is equivalent of applying a negative voltage to the top connection 152, thereby driving the polarization to the left along the hysteresis curve 450 (along dashed line 475) to the lower saturation point 480. Accordingly, the capacitance of the second ferroelectric capacitor 150 corresponds to the slope of the line 490. The signal out at the storage node 130, therefore, corresponds to the ratio of the slope of the line 440 to the slope of the line 490.

Because the hysteresis curves 410 and 450 for ferroelectric capacitors are generally elongated, however, the respective slopes of the lines 440 and 490 are very close, having a ratio close to one. When writing a logic “1” to the circuit, the WRITE operation applies a negative voltage to the ferroelectric capacitors, which reverses the travel path of the polarizations. Thus, during a READ operation reading a “1” from the circuit, the signal out of the storage node 130 corresponds to the ratio of the slope of the line 445 (moving from the lower steady state point 447 to the upper saturation point 420) to the slope of the line 495 (moving from the lower steady state point 497 to the lower saturation point 480). Again, the slopes of these lines are close because of the shape of the hysteresis curves 410 and 450, resulting in a ratio close to one. With the ratios of the slopes of the lines close to one for reading both a “1” and a “0” from the circuit, data read out is difficult to do reliably because the signal difference between the two is small. What signal difference that exists is a result of natural variance in the manufacture of the two ferroelectric capacitors 110 and 150, which variance produces variances in the respective hysteresis curves thereby creating a greater difference in slopes of the respective lines. This variance, however, is increasingly reduced as manufacturing methods for ferroelectric capacitors improves. Accordingly, the expected layout of the ferroelectric capacitors in a voltage divider arrangement in an integrated circuit will not be suitable for normal read/write operations.

To address this shortcoming of the normal arrangement of ferroelectric capacitors in an integrated circuit, an unconventional topology in the integrated circuit is employed. With reference to FIG. 6, an example ferroelectric memory apparatus of unconventional topology includes a circuit 600 includes having a first capacitor 610 electrically coupled to a plate line 1 620 via a top terminal connection 612 and to a storage node 630 via a bottom terminal connection 614. The circuit 600 also includes a second ferroelectric capacitor 650 electrically coupled to a second plate line 2 660 via a second bottom terminal connection 654 and to the storage node 630 via a second top terminal connection 652. In effect, one of the capacitors 110 or 150 of the circuit of FIG. 1 is flipped with respect to the other such that its top connection and bottom connection are connected in reverse to its respective plate line and the storage node.

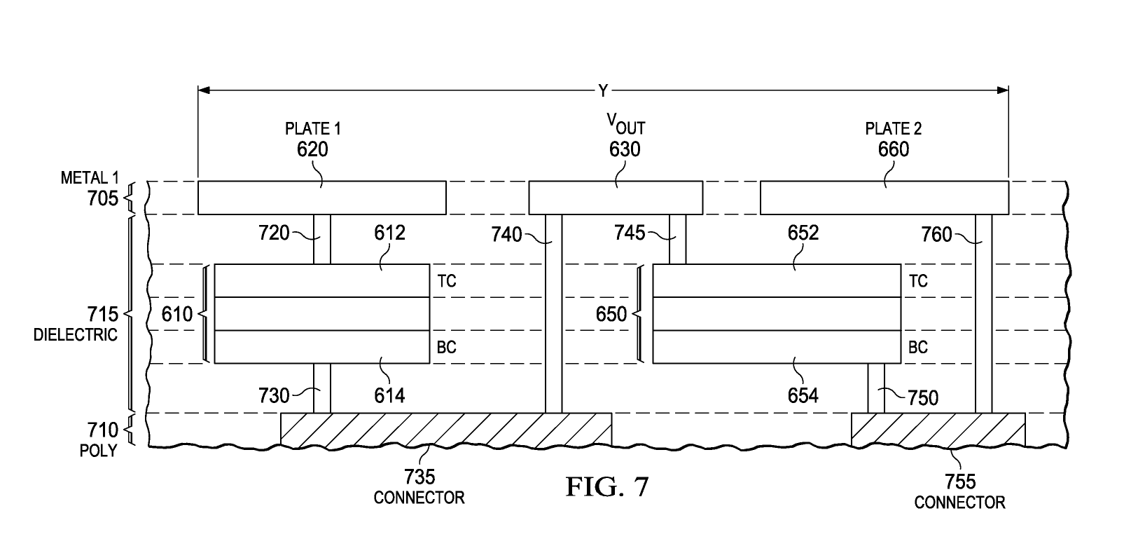

This configuration is unexpected by one of skill in the art because the footprint of such a circuit in an integrated circuit build is larger than that for the configuration of FIGS. 1 and 2. With reference to FIG. 7, an example approach to an integrated circuit build for the circuit of FIG. 6 will be described. Although the elements described in this example are discussed as residing in particular layers, it will be understood that other arrangements are possible. In this example, the ferroelectric capacitors are sandwiched between a metal1 layer 705 and a poly layer 710, although the teachings of this application are applicable to building the capacitors between any integrated circuit layers. The plate line 1 620 and plate line 2 660 are disposed in a single layer of the integrated circuit that may include one of a group comprising a metal1 layer or a metal2 layer (although any metal layer is possible). In the arrangement of FIG. 7, the layer is a metal1 layer 705, although the plate lines could be disposed in different layers. The ferroelectric capacitors 610 and 650 are built in the dielectric layer 715 between the metal1 layer 705 and poly layer 710. An electric connection is established between the top connection 612 and the plate 1 610 by a via 720. The bottom terminal connection 614 of the first ferroelectric capacitor 610 electrically connects to a connector disposed in a second layer of the integrated circuit disposed on a side opposite of a dielectric layer 715 of the integrated circuit. The second layer may be one of a metal layer, a polycrystalline silicon layer, or a transistor source/drain diffusion layer. In the example of FIG. 7, the bottom terminal connection 614 is electrically connected to the storage node 630 by a via 730 to a connector 735 disposed in the poly layer 710, which is in turn electrically connected to the storage node 630 disposed in the metal1 layer 705 (although the storage node 630 can be considered to be several elements electrically connected through more than one layer) by a via through the dielectric layer 715. The second ferroelectric capacitor's 650 top connection 652 is electrically connected to the storage node 630 by a via 745. The bottom terminal connection 614 of the second ferroelectric capacitor 650 electrically connects to a connector disposed in a second layer of the integrated circuit disposed on a side opposite of a dielectric layer 715 of the integrated circuit. In the example of FIG. 7, the bottom terminal connection 654 of the second ferroelectric capacitor 650 is electrically connected to the plate line 2 660 by a via 750 to a second connector 755 disposed in the poly layer 710, which electrically connects to the plate line 2 660 by a via 760 through the dielectric layer 715. As seen by the distance “Y” spanned by the two plate lines 620 and 660, the footprint for this approach to building the circuit 600 of FIG. 6 in an integrated circuit is larger than that of the approach of FIG. 2.

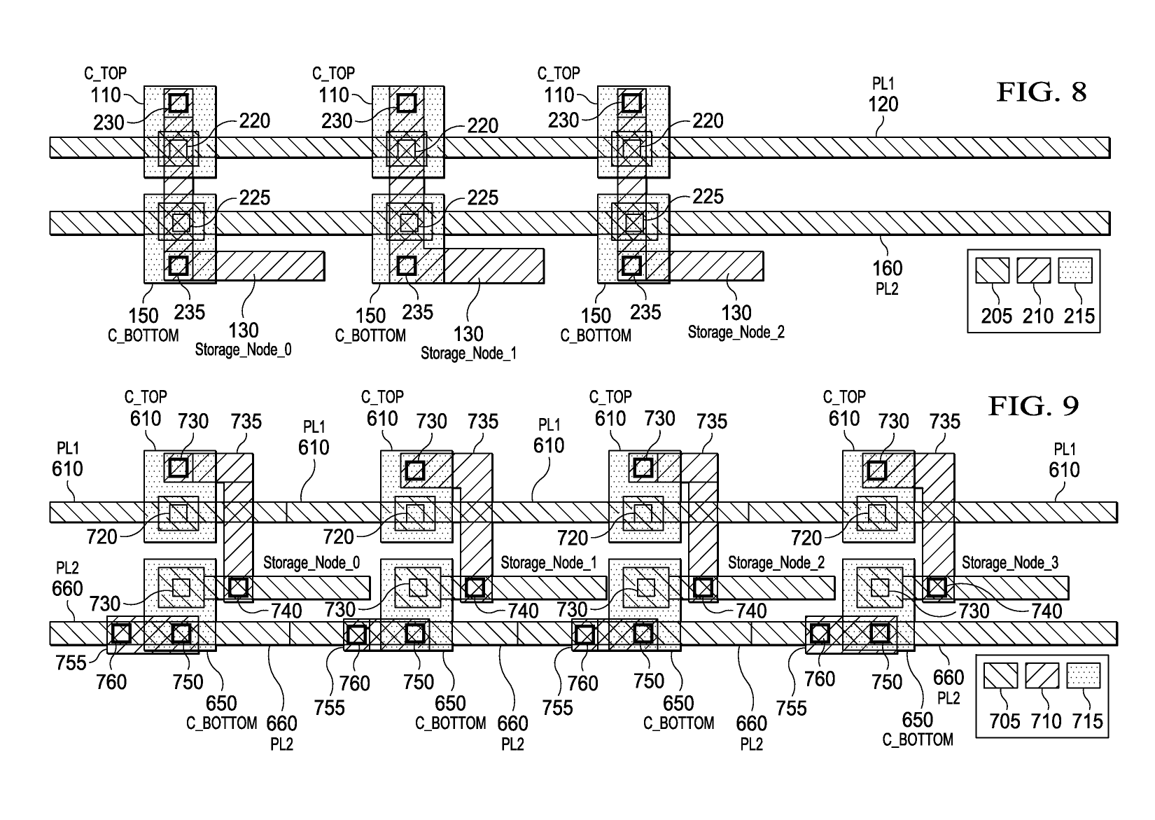

A further comparison of the integrated circuit builds of the two approaches of FIG. 1 and FIG. 6 is shown in FIGS. 8 and 9, which show a plan view of the example silicon builds of the circuits of FIG. 1 and FIG. 6, respectively. As is typical in an integrated circuit, a series of the circuits is laid out one after another as shown in FIGS. 8 and 9. Because of the increased footprint in the silicon build, one of skill in the art would not design a voltage divider type, two ferroelectric capacitor circuits with the top and bottom connections arranged as shown in FIG. 6.

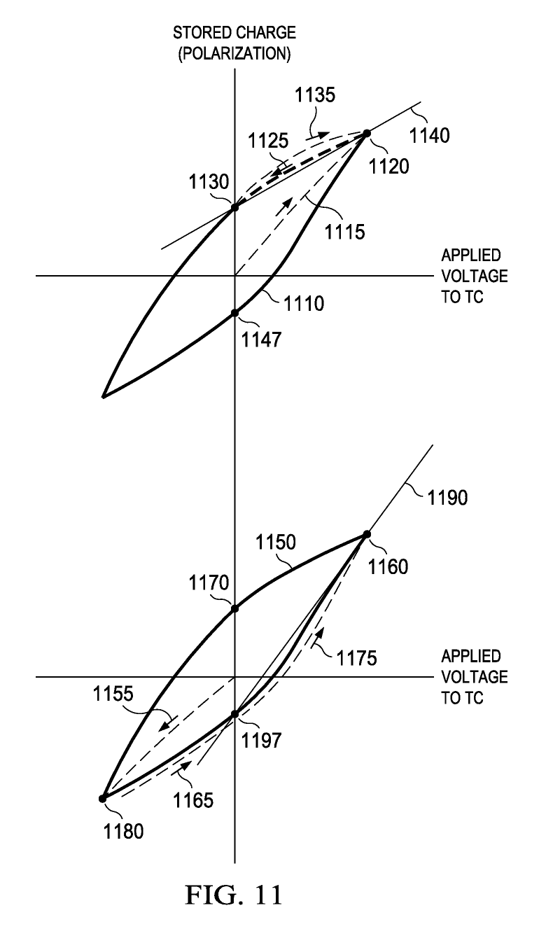

The unexpected advantage of using the design of FIG. 6 over the typical build of FIG. 1 will be described with reference to FIGS. 10-12. During a “WRITE” operation where data is stored in the circuit (in this example, a logic “0”), the storage node 630 is driven to a potential equal to ground potential (representing a logic “0” on the storage node). Subsequently, a positive voltage V is applied to both plate line 1 620 and plate line 2 660 while the storage node 630 is held at ground potential. The voltage V polarizes the ferroelectric capacitors 610 and 650 such that each is left with a remnant polarization after the voltage V is removed. This process is demonstrated with reference to FIG. 11, which shows typical hysteresis curves 1110 and 1150 of ferroelectric capacitors 610 and 650, respectively. The hysteresis curves 1110 and 1150 are plotted to show the stored charge or polarization of the ferroelectric capacitor on the y-axis against an applied voltage along the x-axis. The curves 1110 and 1150 have an elongated shape that is typical of ferroelectric capacitors. When the voltage V is a positive voltage applied to the ferroelectric capacitors 610 and 650, because the top connection 612 of the first ferroelectric capacitor 610 is connected to the plate lines 1 620, the polarization tracks upward along the dashed line 1115 toward a first saturation point 1120. For the second ferroelectric capacitor 650, the bottom connection 654 is connected to the second plate line 2 660; therefore, the positive voltage V appears to the top connection 652 as a negative voltage, which pushes the polarization downward along dashed line 1155 to the lower saturation point 1180. When the voltage V is removed from the ferroelectric capacitors 610 and 650, the polarization moves along the hysteresis curves 1110 and 1115 for each capacitor to a steady state level with applied voltage at zero. For the first ferroelectric capacitor 110, the polarization travels along dashed line 1125 on the hysteresis curve 1110 to a high steady state polarization point 1130 with zero applied voltage. The polarization of the second ferroelectric capacitor 650 moves along dashed line 1165 on the hysteresis curve 1150 to a low steady state polarization point 1197 with zero applied voltage.

With reference to FIG. 12, during a “READ” operation where data stored in the circuit is read from the ferroelectric capacitors 610 and 650, plate line 1 620 is pulsed with a positive voltage while plate line 2 660 is maintained at ground potential. The storage node 630 then reads the signal produced by the ferroelectric capacitors 610 and 650 in response to the voltage pulse. As discussed above, one skilled in the art will recognize that the signal out at the storage node 630 in this voltage divider type of arrangement will be the pulsed voltage multiplied by a ratio of the capacitances of the two ferroelectric capacitors 610 and 650. For ferroelectric capacitors, the capacitance is determined by the slope of the line that the polarization travels on a ferroelectric capacitor's particular hysteresis curve.

Referring again to FIG. 11, when a positive pulse voltage is applied to plate line 1 620 during a READ operation, the positive voltage is applied to the top connection 612 of the first ferroelectric capacitor 610, which drives the polarization of the capacitor 610 back up the hysteresis curve 1110 from the high steady state point 1130 along dashed line 1135 back to the high saturation point 1120. Accordingly, the capacitance of the first ferroelectric capacitor 610 corresponds to the slope of the line 1140.

The positive pulse voltage applied to plate line 1 620 during the READ operation applies a positive voltage to the top connection 652 of the second ferroelectric capacitor 650, thereby driving the polarization to the right along the hysteresis curve 1150 (along dashed line 1175) to the high saturation point 1160. Accordingly, the capacitance of the second ferroelectric capacitor 150 corresponds to the slope of the line 1190. The signal out at the storage node 630, therefore, corresponds to the ratio of the slope of the line 1140 to the slope of the line 1190. In this configuration, the polarizations of the ferroelectric capacitors track opposite portions of their respective hysteresis curves 1110 and 1150: the first ferroelectric capacitor 610 tracking the upper portion of its hysteresis curve 1110 and the second ferroelectric capacitor 650 tracking the bottom portion of its hysteresis curve 1150. By tracking different portions of the respective curves, the slopes of the two lines 1140 and 1190 differ by a greater margin than in the approach of FIGS. 1-5. This holds true when a logic “1” is written by applying a negative voltage V during the WRITE operation, resulting in the first ferroelectric capacitor 610 tracking the lower portion of its hysteresis curve 1110 (starting the READ operation at the low steady state point 1147) and the second ferroelectric capacitor 650 tracking the upper portion of its hysteresis curve 1150 (starting the READ operation at the high steady state point 1170).

So configured, an improvement in the minimum logic 1 to logic 0 voltage differential is realized, even when the ferroelectric capacitors are similarly made with very similar polarization hysteresis curves. With this approach, the signal to noise ratio is reliably large enough to ensure good signals regardless of the manufacturing variance among paired ferroelectric capacitors.

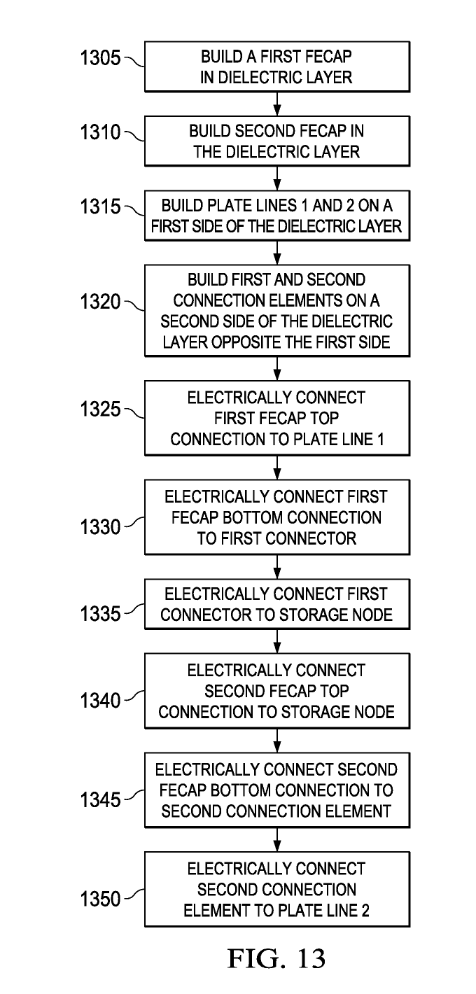

An example method of making a ferroelectric apparatus such as that taught in this specification will be described with reference to FIG. 13. The method includes building 1305 a first ferroelectric capacitor in a dielectric layer of an integrated circuit. The first ferroelectric capacitor includes a top terminal connection oriented toward a first layer of the integrated circuit on a first side of the dielectric layer and a bottom terminal connection oriented toward a second layer of the integrated circuit on a second side of the dielectric layer opposite the first layer of the integrated circuit. It will be understood that the terminology “first” and “second layer” and “first” and “second side” will refer to silicon layers not necessarily immediately adjacent to the dielectric layer. The method also includes building 1310 a second ferroelectric capacitor in the dielectric layer of the integrated circuit. The second ferroelectric capacitor has a second top terminal connection oriented toward the first layer of the integrated circuit on the first side of the dielectric layer and a second bottom terminal connection oriented toward the second layer of the integrated circuit on the second side of the dielectric layer opposite the first layer of the integrated circuit. A plate line and a second plate line are built 1315 in one or more layers on the first side of the integrated circuit, and a first connection element and a second connection element are built 1320 in one or more layers on the second side of the integrated circuit. One of skill in the art understands the process behind building individual elements such as those described herein into an integrated circuit, and the details of such are therefore omitted for brevity.

The method further includes building various electrical connections as known in the art between various ones of the elements. For instance, the method includes electrically connecting 1325 the top connection of the first ferroelectric capacitor to the first plate line, and electrically connecting 1330 the bottom connection of the first ferroelectric capacitor to the first connection element. The first ferroelectric capacitor is then electrically connected to the storage node by electrically connecting 1335 the first connection element to a storage node. The method further includes electrically connecting 1340 the second top connection of the second ferroelectric capacitor to the storage node, and electrically connecting 1345 the second bottom connection of the second ferroelectric capacitor to the second connection element. The second ferroelectric capacitor is then connected to the second plate line by electrically connecting 1350 the second connection element to the second plate line. The plate lines and storage node are connected to controlling circuitry in a manner known in the art for controlling ferroelectric capacitor based devices.

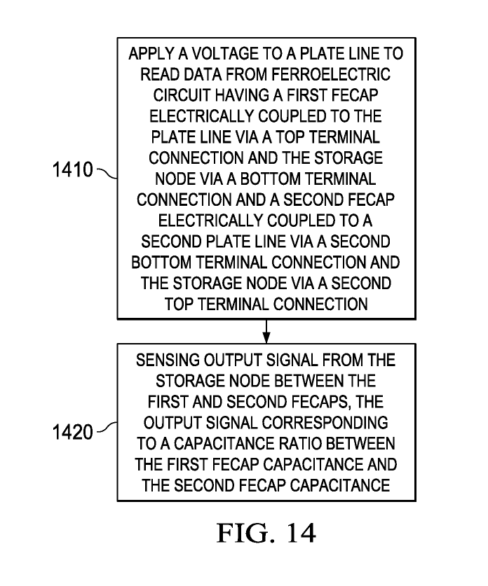

An example method of operating a ferroelectric memory device will be described with reference to FIG. 14. The method includes applying 1410 a voltage to a plate line to read a signal from a storage node of a ferroelectric circuit. The ferroelectric circuit has a first ferroelectric capacitor electrically coupled to the plate line via a top terminal connection and the storage node via a bottom terminal connection. The ferroelectric circuit also has a second ferroelectric capacitor electrically coupled to a second plate line via a second bottom terminal connection and the storage node via a second top terminal connection. The method further includes sensing 1420 an output signal from the storage node disposed between the first ferroelectric capacitor and the second ferroelectric capacitor. In this approach, the output signal corresponds to a capacitance ratio between the first ferroelectric capacitor's capacitance and the second ferroelectric capacitor's capacitance after a write operation on the circuit.

Those skilled in the art will recognize that a wide variety of modifications, alterations, and combinations can be made with respect to the above described embodiments without departing from the scope of the invention. For example, the example of FIG. 12 can be understood as illustrating one example approach, whereas in another approach, capacitor 610 and capacitor 650 can both be flipped with respect to their respective the top and bottom connections, and such an arrangement will provide the desired improvement in electrical performance. Such modifications, alterations, and combinations are to be viewed as being within the ambit of the inventive concept.

What is claimed is:

1. A ferroelectric apparatus comprising:
a circuit having at least:
a first ferroelectric capacitor electrically coupled to:
a plate line via a top terminal connection of the first ferroelectric capacitor, and
a storage node via a bottom terminal connection of the first ferroelectric capacitor;
a second ferroelectric capacitor electrically coupled to:
a second plate line via a second bottom terminal connection of the second ferroelectric capacitor, and
the storage node via the a second top terminal connection of the second ferroelectric capacitor.

2. The ferroelectric apparatus of claim 1 wherein the plate line and the second plate line are disposed in a single layer of an integrated circuit.

3. The ferroelectric apparatus of claim 2 wherein the single layer comprises one of the group comprising a metal 1 layer or a metal 2 layer.

4. The ferroelectric apparatus of claim 2 wherein the bottom terminal connection of the first ferroelectric capacitor electrically connects to a connector disposed in a second layer of the integrated circuit disposed on a side opposite of a dielectric layer of the integrated circuit.

5. The ferroelectric apparatus of claim 4 wherein the second layer comprises one of metal layer, a polycrystalline silicon layer, or a transistor source/drain diffusion layer.

6. The ferroelectric apparatus of claim 2 wherein the bottom terminal connection of the second ferroelectric capacitor electrically connects to a connector disposed in a second layer of the integrated circuit disposed on a side opposite of a dielectric layer of the integrated circuit.

7. The ferroelectric apparatus of claim 4 wherein the second layer comprises one of a metal layer, a polycrystalline silicon layer, or a transistor source/drain diffusion layer.

8. A method of making a ferroelectric apparatus, the method comprising:
building a first ferroelectric capacitor in a dielectric layer of an integrated circuit, the first ferroelectric capacitor having a top terminal connection oriented toward a first layer of the integrated circuit on a first side of the dielectric layer and a bottom terminal connection oriented toward a second layer of the integrated circuit on a second side of the dielectric layer opposite the first layer of the integrated circuit;
building a second ferroelectric capacitor in the dielectric layer of the integrated circuit, the second ferroelectric capacitor having a second top terminal connection oriented toward the first layer of the integrated circuit on the first side of the dielectric layer and a second bottom terminal connection oriented toward the second layer of the integrated circuit on the second side of the dielectric layer opposite the first layer of the integrated circuit;
building a plate line and a second plate line in one or more layers on the first side of the integrated circuit;
building a first connection element and a second connection element in one or more layers on the second side of the integrated circuit;
electrically connecting the top connection of the first ferroelectric capacitor to the first plate line;
electrically connecting the bottom connection of the first ferroelectric capacitor to the first connection element;
electrically connecting the first connection element to a storage node;
electrically connecting the second top connection of the second ferroelectric capacitor to the storage node;
electrically connecting the second bottom connection of the second ferroelectric capacitor to the second connection element;
electrically connecting the second connection element to the second plate line.

9. The method of claim 8 wherein the first layer of the integrated circuit comprises one of the group comprising a metal 1 layer or a metal 2 layer.

10. The method of claim 8 wherein the second layer of the integrated circuit comprises one of metal layer, a polycrystalline silicon layer, or a transistor source/drain diffusion layer.

11. A ferroelectric apparatus comprising:
a first ferroelectric capacitor built in a dielectric layer of an integrated circuit, the first ferroelectric capacitor electrically coupled to:
a plate line built in a layer of the integrated circuit on a first side of the dielectric layer through a via between a top terminal connection of the ferroelectric capacitor and the plate line, and
a storage node built on the first side of the dielectric layer through an electrical connection of a bottom terminal connection of the ferroelectric capacitor to a connector built in a second layer of the integrated circuit on a second side of the dielectric layer opposite the first side of the dielectric layer, wherein the connector is electrically connected to the storage node through a via through the dielectric layer;
a second ferroelectric capacitor built in the dielectric layer of the integrated circuit, the second ferroelectric capacitor electrically coupled to:
a second plate line built in a layer on the first side of the dielectric layer of the integrated circuit through an electrical connection between a second bottom terminal connection to a second connector built in a layer on the second side of the dielectric layer of the integrated circuit, wherein the second connector is electrically connected to the second plate line through a via through the dielectric layer, and
the storage node through a via between a second top terminal connection and the storage node.

12. The ferroelectric apparatus of claim 11 wherein the first layer comprises one of the group comprising a metal 1 layer or a metal 2 layer.

13. The ferroelectric apparatus of claim 11 wherein the second layer comprises one of the group comprising a metal 1 layer, a metal 2 layer, a polycrystalline silicon layer, or a transistor source/drain diffusion connection.
